(19) United States
(12) Patent Application Publication
(10) Pub. No.: US 2009/0198462 A1
(43) Pub. Date: Aug. 6, 2009

(54) Method, system and analog stimulus-response unit for determining real and imaginary components of an AC response received from a device under test

(76) Inventor: John Elliott McDermid, Loveland, CO (US)

Correspondence Address: AGILENT TECHNOLOGIES INC., INTELLECTUAL PROPERTY ADMINISTRATION,LEGAL DEPT., MS BLDG. E P.O. BOX 7599, LOVELAND, CO, 80537, US

(21) Appl. No.: 12/012,021

(22) Filed: Jan. 31, 2008

(51) Int. Cl. G01R 23/16

(52) U.S. Cl. 702/77

(57) ABSTRACT

In one embodiment, samples of an AC response received from a device under test (DUT) are acquired at an interval, Δt, of k/(fₜₑₛₜN), where k is a number of a discrete frequency response, where fₜₑₛₜ is a test frequency of an AC stimulus applied to the DUT, where the test frequency is an integer multiple, M, of a periodic frequency, f, where N is the number of samples acquired, and where M=2k. The real and imaginary components of the AC response are determined, while rejecting the periodic frequency, by processing the samples of the AC response through a discrete Fourier transform.

### BACKGROUND

There are many situations in which it may be necessary to determine the real and imaginary components of an alternating current (AC) response received from a device under test (DUT). One situation is the characterization of an impedance of a DUT. For example, to determine the value of a capacitor, an analog stimulus-response unit (ASRU) may 1) apply an alternating current (AC) stimulus to the capacitor, 2) receive an AC response from the capacitor (e.g., a time-varying voltage across the capacitor), 3) use the AC response to determine the real and imaginary components of the AC response, and then 4) determine the value of the capacitor from the imaginary component of the AC response.

To properly determine the real and imaginary components of an AC response, it is often necessary to remove certain periodic waveforms, or noise, from the AC response. One periodic waveform that often needs to be removed is the line frequency (sometimes called “power line frequency”) of a test system's power mains. As described herein, line frequency rejection (i.e., removal of the effects of a line frequency from an AC response) is usually performed in the time domain.

### BRIEF DESCRIPTION OF THE DRAWINGS

Illustrative embodiments of the invention are illustrated in the drawings, in which:

FIG. 1 illustrates a first exemplary ASRU;

FIG. 2 illustrates a Bode plot of the discrete Fourier transform (DFT) for an ASRU test frequency of 1080 Hz, and for k=1 and k=9, respectively;

FIG. 3 illustrates an exemplary method for determining the real and imaginary components of an AC response received from a DUT;

FIG. 4 illustrates a first exemplary system for implementing steps of the method shown in FIG. 3; and

FIG. 5 illustrates a second exemplary system (an ASRU) for implementing steps of the method shown in FIG. 3.

### DETAILED DESCRIPTION

As a preliminary manner, it is noted that, in the following description, like reference numbers appearing in different drawing figures refer to like elements/features.

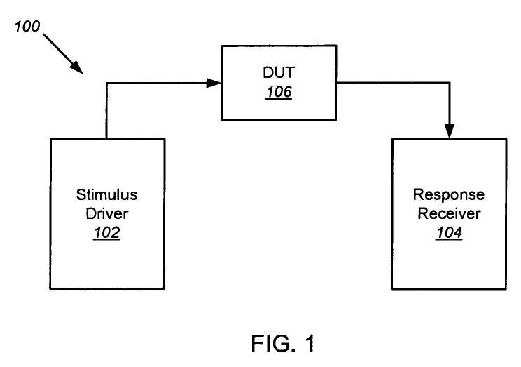

FIG. 1 illustrates an exemplary ASRU 100 comprising a driver 102 for applying a stimulus to a DUT 106, and a receiver 104 for receiving a response from the DUT 106. The ASRU 100 applies an AC stimulus to the DUT 106 and receives an AC response from the DUT 106. In some embodiments, the ASRU 100 may also apply a DC stimulus to the DUT 106 and receive a DC response from the DUT 106. However, of importance to this description are the methods and apparatus by which AC stimuli and responses are applied to (and received from) the DUT 106.

By way of example, the DUT 106 could be a discrete component, such as a resistor, capacitor or inductor. Alternately, and by way of further example, the DUT 106 could be a network of impedances, a signal path such as a wire or printed circuit board trace, or an input or output of a more complex device such as an integrated circuit. In some embodiments, the DUT 106 may stand apart from other components, as would be the case of testing a discrete resistor. In other embodiments, the DUT 106 may be embedded in, or connected to, other circuitry that is not under test. In the latter case, the ASRU 100 or other equipment may take steps to condition or guard the “other circuitry” during test of the DUT 106.

In one embodiment, the ASRU 100 can be implemented as the HP3253 ASRU. The HP3253 was originally offered by Hewlett-Packard Company, but is now offered by Agilent Technologies, Inc. of Santa Clara, Calif. The HP3253 determines the complex components (real and imaginary components) of an AC voltage response by means of integration. For example, the HP3253 determines the “real” component of an AC response by integrating the AC response over the first half-cycle of a sinusoidal test frequency, f, and then adding to this quantity a negative integration of the AC response over the second half-cycle of the test frequency. Mathematically, this can be written as:

$${V}_{RMS} = \frac{π}{2 \sqrt{2}} \frac{( {\int }_{0}^{T / 2} \sqrt{2} A sin ( 2 π ft ) d t + {\int }_{T / 2}^{T} \sqrt{2} A sin ( 2 π ft ) d t )}{T} , \qquad ( Eq . 1 )$$

where \sqrt{2}A is the peak amplitude of the AC response, where f is the test frequency in Hertz, and where

$$\frac{π}{2 \sqrt{2}}$$

is a constant necessary to convert an average value to a root-mean-square (RMS) value, V_{RMS}.

Eq. 1 is represented by the MATLAB® software (offered by The Mathworks of Natick, Mass.) as follows:

$${V}_{RMS} = \frac{A ( 1 - 2 cos ( π fT ) + cos ( 2 π fT ) )}{fT} . \qquad ( Eq . 2 )$$

If T is chosen to be the period of the test frequency, then the above equation simplifies to V_{RMS}=A.

Delaying the integration of the AC response by T/4 with respect to the integration performed for the “real” component returns the “imaginary” component of the AC response. With a knowledge of the real and imaginary components of the AC response, and by way of example, the values of components such as inductors and capacitors, and the effective impedances of networks, can be determined as is known in the art.

Line frequency rejection can be achieved for the measurements made in Eq. 1 or Eq. 2 by integrating for a full line cycle. This method is employed in the Agilent 3070 Board Test System, which integrates multiple half-cycles of the test frequency, f, and then averages the result of the integration over the full period of a line cycle. The averaged result, Ave, is:

$$Ave = ( \frac{M}{T} ) {\sum }_{n = 1}^{M} {\int }_{2 ( n - 1 ) \frac{T}{M}}^{( {2}^{*} n - 1 ) \frac{T}{M}} \sqrt{2} sin ( 2 π t / T + Φ ) d t / M \qquad ( Eq . 3 )$$

When Eq. 3 is evaluated for any phase, Φ, of the AC response, and for M=17 (the value of M used by the Agilent 3070 for an ˜1 KHz stimulus), the result is Ave=0. This provides line frequency rejection for a 60 Hz line while making an accurate measurement of the test frequency, f.

The above-described method may be used to reject (remove) line frequency from both the real and imaginary components of an AC response.

The above-described embodiments of the ASRU 100 determine the real and imaginary components of an AC response in the time domain. Another way to determine the complex components of an AC response is in the frequency domain, by sampling the AC response of the DUT 106 and processing the samples through a discrete Fourier transform (DFT). If the samples are acquired at discrete time intervals, the AC response can also be expressed at discrete frequencies. That is, the DFT can be expressed as follows:

$$\begin{matrix}D F T = V ( k Δ ω ) \\ = \frac{\sqrt{2}}{N} {\sum }_{n = 0}^{N} ( V ( n ) sin ( 2 π kn / N ) + j V ( n ) cos ( 2 π kn / N ) ) ,\end{matrix} \qquad ( Eq . 4 )$$

where N is the number of samples, V(n) are the measured voltages, and k is the number of the discrete frequency response. If the DUT 106 is stimulated using a sine wave with frequency ω=kΔω, then the DFT of the AC voltage response, V(kΔω), returns the real and imaginary components of the AC response.

Sampling an AC response and applying a DFT provides the same result as can achieved by integrating half-cycles of the AC response. Higher values of k require sampling to occur over a longer time.

Little attention has been paid to the frequency response of the DFT at signal frequencies other than ω=kΔω. The analysis (shown below) shows that certain restrictions on M and k will provide line frequency rejection, but with improved properties. The first restriction is that an AC stimulus having a test frequency, fₜₑₛₜ, be applied to the DUT 106 as an integer multiple, M, of the line frequency, f, of the ASRU 100 (i.e., f=M*fₜₑₛₜ). The second restriction is that the AC response of the DUT 106 be sampled at an interval, Δt, of k/fₜₑₛₜN (i.e., Δt=k/(fₜₑₛₜN)), where N is the number of samples taken. With these restrictions, Eq. 4 is represented by the MATLAB® software as follows:

$$DFT = - 2 * ( 2 {cos ( π Mk )}^{2} sin ( π k ) cos ( π k ) cos ( Φ ) {cos ( \frac{π Mk}{N} )}^{3} - sin ( π k ) cos ( π k ) cos ( Φ ) {cos ( \frac{π Mk}{N} )}^{3} - 2 sin ( π Mk ) cos ( π Mk ) sin ( π k ) cos ( π k ) sin ( Φ ) {cos ( \frac{π Mk}{N} )}^{3} - sin ( π k ) cos ( π k ) sin ( \frac{π Mk}{N} ) {cos ( \frac{π Mk}{N} )}^{2} sin ( Φ ) + 2 {cos ( π Mk )}^{2} sin ( π k ) cos ( π k ) sin ( \frac{π Mk}{N} ) sin ( Φ ) {cos ( \frac{π Mk}{N} )}^{2} + 2 sin ( π Mk ) cos ( π Mk ) sin ( π k ) cos ( π k ) sin ( \frac{π Mk}{N} ) cos ( Φ ) {cos ( \frac{π Mk}{N} )}^{2} - 2 {cos ( π Mk )}^{2} sin ( π k ) cos ( π k ) cos ( Φ ) cos ( \frac{π Mk}{N} ) + sin ( π k ) cos ( π k ) cos ( Φ ) cos ( \frac{π Mk}{N} ) + 2 sin ( π Mk ) cos ( π Mk ) sin ( π k ) cos ( π k ) sin ( Φ ) cos ( \frac{π Mk}{N} ) + sin ( π k ) cos ( π k ) sin ( \frac{π Mk}{N} ) sin ( Φ ) {cos ( \frac{π k}{N} )}^{2} - 2 {cos ( π Mk )}^{2} sin ( π k ) cos ( π k ) sin ( \frac{π Mk}{N} ) sin ( Φ ) {cos ( \frac{π k}{N} )}^{2} - 2 sin ( π Mk ) cos ( π Mk ) sin ( π k ) cos ( π k ) sin ( \frac{π Mk}{N} ) cos ( Φ ) {cos ( \frac{π k}{N} )}^{2} - sin ( \frac{π k}{N} ) cos ( \frac{π k}{N} ) sin ( π Mk ) cos ( π Mk ) cos ( Φ ) sin ( \frac{π Mk}{N} ) - sin ( \frac{π k}{N} ) cos ( \frac{π k}{N} ) sin ( Φ ) {cos ( π Mk )}^{2} sin ( \frac{π Mk}{N} ) - sin ( \frac{π k}{N} ) cos ( \frac{π k}{N} ) sin ( Φ ) {cos ( π k )}^{2} sin ( \frac{π Mk}{N} ) + 2 sin ( Φ ) sin ( \frac{π k}{N} ) cos ( \frac{π k}{N} ) {cos ( π Mk )}^{2} {cos ( π k )}^{2} sin ( \frac{π Mk}{N} ) + 2 cos ( Φ ) sin ( \frac{π k}{N} ) cos ( \frac{π k}{N} ) sin ( π Mk ) cos ( π Mk ) {cos ( π k )}^{2} sin ( \frac{π Mk}{N} ) ) / ( ( {cos ( \frac{π Mk}{N} )}^{2} - {cos ( \frac{π k}{N} )}^{2} ) * N sin ( \frac{π M k}{N} ) \qquad ( Eq . 5 )$$

When a further restriction on M is applied, such that M=2k, line frequency rejection can be attained. For example, choosing k=9 and M=18 makes a test frequency of approximately 1 KHz. Evaluating Eq. 5 at these values of M and k yields a result of DFT=0. This demonstrates that, under the stated restrictions, line frequency rejection is achieved for any arbitrary phase, Φ, of line frequency.

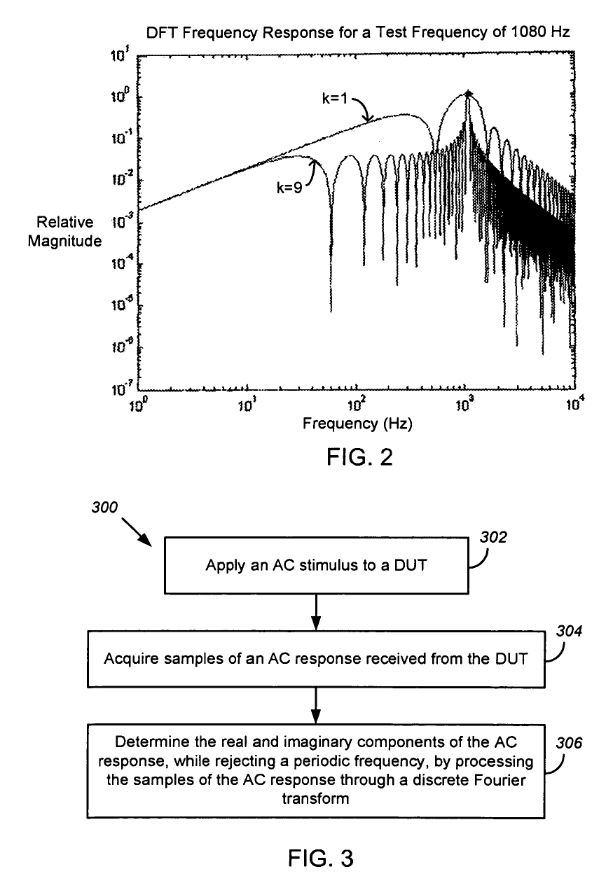

Given the previously-recited restrictions on M and k, FIG. 2 illustrates a Bode plot of the DFT for a test frequency of 1080 Hz, and for k=1 and k=9, respectively. An asterisk indicates the sample point. Note that there are 16 points of rejection at harmonics of the line frequency beyond the fundamental frequency (60 Hz).

Turning now to FIG. 3, and in accord with at least some of the above teachings, there is shown an exemplary method 300 for determining the real and imaginary components of an AC response received from a DUT. The method 300 comprises 1) acquiring samples of the AC response (at block 304), and 2) determining the real and imaginary components of the AC response by processing the samples of the AC response through a discrete Fourier transform (at block 306). The samples are acquired at an interval, Δt, of k/(fₜₑₛₜN), where k is a number of a discrete frequency response, where fₜₑₛₜ is a test frequency of an AC stimulus applied to the DUT, where the test frequency is an integer multiple, M, of a periodic frequency, f, where N is the number of samples acquired, and where M=2k. By acquiring the samples with these restrictions, the periodic frequency, f, may be rejected when determining the real and imaginary components of the AC response received from the DUT.

The method 300 may further comprise the step of applying the AC stimulus to the DUT, at the test frequency, fₜₑₛₜ (at block 302).

In many cases, the periodic frequency rejected by the method 300 may be a power line frequency. However, the periodic frequency could also be another source of noise that might interfere with the AC response of a DUT.

Typically, the acquired samples will be voltage samples.

In some embodiments of the method 300, k and M may be selected such that k=9 and M=18, although many other combinations of values are possible.

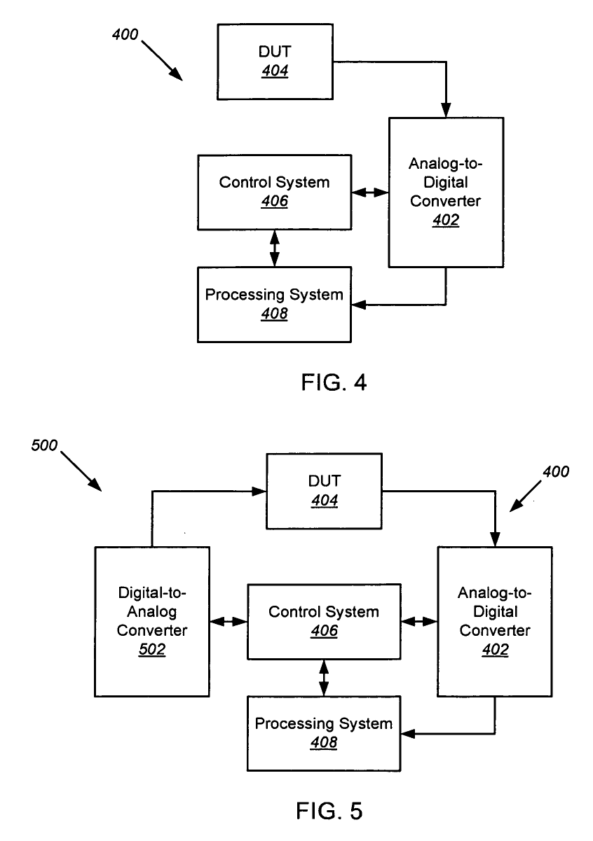

The method 300 may in some cases be implemented by the system 400 shown in FIG. 4. The system 400 comprises an analog-to-digital converter 402 that is configured to receive an AC response from a DUT 404. The system 400 also comprises a control system 406 that is configured to cause the analog-to-digital converter 402 to acquire digital samples of the AC response, at an interval, Δt, of k/(fₜₑₛₜN), where k is a number of a discrete frequency response, where fₜₑₛₜ is a test frequency of an AC stimulus applied to the DUT, where the test frequency is an integer multiple, M, of a periodic frequency, f, where N is the number of samples acquired, and where M=2k. The system 400 further comprises a processing system 408 that is configured to determine the real and imaginary components of the AC response, while rejecting the periodic frequency, by processing the samples of the AC response through a discrete Fourier transform.

The components 402, 406, 408 of the system 400 may be implemented in various ways. For example, the components 402, 406, 408 may be integrated within a single integrated circuit, on a single printed circuit board, or on multiple integrated circuits and/or printed circuit boards. Some or all of the components 402, 406, 408 may be implemented via a microprocessor or field-programmable gate array (FPGA). The components 402, 406, 408 may also be implemented via hardware, or via a combination of hardware and software (or firmware).

In some cases, the system 400 shown in FIG. 4 may be incorporated into a larger test system, such as an ASRU 500. In this case, the ASRU 500 may further comprise a digital-to-analog converter 502 that is configured to apply an AC stimulus, to the DUT 404, at the test frequency, fₜₑₛₜ.

One advantage to using the methods 300 or systems 400, 500 described herein is that they provide line frequency rejection, or rejection of a predetermined period frequency, at one-half the period of a line cycle (or at one-half the period of a periodic noise signal). In contrast, previous methods and systems took one full cycle of the line frequency to reject the frequency. That is, using the methods 300 or systems 400, 500 described herein, a periodic frequency, f, can be rejected after a sample period, tₛₐₘₚₗₑ, of T/2. Put another way,

$${t}_{xample} = N Δ t = \frac{k}{{f}_{test}} = \frac{k}{Mf} = \frac{kT}{M} = \frac{T}{2} , \qquad ( Eq . 6 )$$

where T=1/f.

Providing rejection at twice the rate of past methods and systems can provide a significant advantage when testing DUTs such as printed circuit (PC) boards using analog in-circuit test methods. PC board throughput directly affects the cost of a PC board. Reducing the time required to test a component on a PC board provides a significant cost advantage for manufacture of the PC board.

What is claimed is:

1. A method for determining real and imaginary components of an AC response received from a device under test (DUT), comprising:
acquiring samples of the AC response received from the DUT, at an interval, Δt, of k/(fₜₑₛₜN), where k is a number of a discrete frequency response, where fₜₑₛₜ is a test frequency of an AC stimulus applied to the DUT, where the test frequency is an integer multiple, M, of a periodic frequency, f, where N is the number of samples acquired, and where M=2k; and
determining the real and imaginary components of the AC response, while rejecting the periodic frequency, by processing the samples of the AC response through a discrete Fourier transform.

2. The method of claim 1, wherein the samples of the AC response are voltages.

3. The method of claim 1, wherein the periodic frequency is a power line frequency.

4. The method of claim 1, wherein k=9 and M=18.

5. The method of claim 1, further comprising, rejecting the periodic frequency after a sample period of T/2, where T=1/f .

6. The method of claim 1, further comprising, applying an AC stimulus to the DUT, at the test frequency, fₜₑₛₜ.

7. A system for determining real and imaginary components of an AC response received from a device under test (DUT), comprising:
an analog-to-digital converter configured to receive the AC response from the DUT;
a control system configured to cause the analog-to-digital converter to acquire digital samples of the AC response, at an interval, Δt, of k/(fₜₑₛₜN), where k is a number of a discrete frequency response, where fₜₑₛₜ is a test frequency of an AC stimulus applied to the DUT, where the test frequency is an integer multiple, M, of a periodic frequency, f, where N is the number of samples acquired, and where M=2k; and
a processing system configured to determine the real and imaginary components of the AC response, while rejecting the periodic frequency, by processing the samples of the AC response through a discrete Fourier transform.

8. The system of claim 7, wherein the periodic frequency is a power line frequency.

9. The system of claim 7, wherein k=9 and M=18.

10. The system of claim 7, wherein the processing system rejects the periodic frequency after a sample period of T/2, where T=1/f.

11. The system of claim 7, wherein the samples of the AC response are voltages.

12. An analog stimulus-response unit (ASRU), comprising:
a digital-to-analog converter configured to apply an AC stimulus to a device under test (DUT), at a test frequency, fₜₑₛₜ, that is an integer multiple, M, of a periodic frequency, f;
an analog-to-digital converter configured to receive an AC response from the DUT;
a control system configured to cause the analog-to-digital converter to acquire digital samples of the AC response, at an interval, Δt, of k/(fₜₑₛₜN), where k is a number of a discrete frequency response, where N is the number of samples acquired, and where M=2k; and
a processing system configured to determine real and imaginary components of the AC response, while rejecting the periodic frequency, by processing the samples of the AC response through a discrete Fourier transform.

13. The ASRU of claim 12, wherein the periodic frequency is a power line frequency of the ASRU.

14. The ASRU of claim 12, wherein k=9 and M=18.

15. The ASRU of claim 12, wherein the processing system rejects the periodic frequency after a sample period of T/2, where T=1/f.

16. The ASRU of claim 14, wherein the samples of the AC response are voltages.
